(19) United States
(12) Patent Application Publication
(10) Pub. No.: US 2024/0213364 A1
(43) Pub. Date: Jun. 27, 2024

(54) SEMICONDUCTOR DEVICE AND MANUFACTURING METHOD FOR SEMICONDUCTOR DEVICE

(71) Applicant: NATIONAL INSTITUTE OF ADVANCED INDUSTRIAL SCIENCE AND TECHNOLOGY, Tokyo (JP)

(72) Inventors: Yoshinao MIURA, Tsukuba-shi (JP); Akira NAKAJIMA, Tsukuba-shi (JP); Xu-Qiang SHEN, Tsukuba-shi (JP); Hirohisa HIRAI, Tsukuba-shi (JP); Shinsuke HARADA, Tsukuba-shi (JP)

(21) Appl. No.: 18/556,293

(22) PCT Filed: Apr. 15, 2022
(86) PCT No.: PCT/JP2022/017898

§ 371 Date: Oct. 19, 2023

(30) Foreign Application Priority Data
Apr. 22, 2021 (JP) 2021-072595

(51) Int. Cl. H01L 29/78; H01L 21/265; H01L 29/20; H01L 29/861

(52) U.S. Cl. CPC H01L 29/7811; H01L 21/265; H01L 29/2003; H01L 29/7813; H01L 29/8613

(57) ABSTRACT

There is provided a semiconductor equipment including: an element area having an n-type layer, a first p-type layer on the n-type layer, and a second p-type layer on the first p-type layer, the second p-type layer having an acceptor concentration higher than the first p-type layer; and an electric field relaxation region surrounding the element area, in which in the electric field relaxation region, a region containing an impurity element that inactivates a part of acceptors in the first p-type layer and the second p-type layer is provided in the first p-type layer and the second p-type layer.

### TECHNICAL FIELD

The present invention relates to a semiconductor equipment and a manufacturing method for the same, and more particularly to a nitride semiconductor equipment and a manufacturing method for the same.

Priority is claimed on Japanese Patent Application No. 2021-072595, filed in Japan on Apr. 22, 2021, the content of which is incorporated herein by reference.

### BACKGROUND ART

A technique has been proposed to improve a withstand voltage of a nitride semiconductor equipment by forming a terminal structure in which a p-type guard ring portion is provided around an active portion and an i-type or n-type ion implantation region is further provided around the guard ring portion (see, for example, Patent Document 1).

A technique has been proposed to provide an electric field relaxation region in which a p-layer is thinned by forming a recess groove around an element area to make it easy for the electric field relaxation region to be depleted when a voltage is applied, thereby relaxing an electric field at an edge of the element area and increasing a withstand voltage of an entire element (see, for example, Patent Document 2).

### CITATION LIST

### Patent Documents

### Patent Document 1

Japanese Unexamined Patent Application, First Publication No. 2019-186429 (A)

### Patent Document 2

Japanese Unexamined Patent Application, First Publication No. 2017-183428 (A)

### SUMMARY OF INVENTION

### Technical Problem

However, in Patent Document 1, a depletion layer spreads between the p-type guard ring portion and the adjacent i-type or n-type ion implantation region along a surface of a nitride semiconductor layer having the terminal structure, and an electric field is applied. Such a guard ring structure has a problem in that local electric field concentration is likely to occur. In Patent Document 2, since the inside of the electric field relaxation region is the p-layer, electric field concentration can be avoided, but there is a problem in that electric field concentration is likely to occur at inner and outer ends of the electric field relaxation region. Furthermore, there is a problem in that it is not easy to precisely control a thickness in order to make the p-layer thin, and application to the production process is difficult.

An object of the present invention is to provide a semiconductor equipment and a manufacturing method for the same capable of improving a withstand voltage by suppressing electric field concentration in a terminal region surrounding an element area.

### Solution to Problem

According to an aspect of the present disclosure, there is provided a semiconductor equipment including: an element area having an n-type layer, a first p-type layer on the n-type layer, and a second p-type layer on the first p-type layer, the second p-type layer having an acceptor concentration higher than the first p-type layer; and an electric field relaxation region surrounding the element area, in which in the electric field relaxation region, a region containing an impurity element that inactivates a part of acceptors in the first p-type layer and the second p-type layer is provided in the first p-type layer and the second p-type layer.

According to the above aspect, in the electric field relaxation region surrounding the element area, the region containing the impurity element that inactivates a part of the acceptor is formed in the first p-type layer and the second p-type layer. In the region containing an impurity element, a part of the acceptor is inactivated to increase the resistance. Therefore, formation of an electric field concentration point where an electric field is locally concentrated can be suppressed, and a withstand voltage of the semiconductor equipment can be improved.

According to another aspect of the present disclosure, there is provided a manufacturing method for a semiconductor equipment, including: a step of forming an n-type layer, a first p-type layer on the n-type layer, and a second p-type layer on the first p-type layer on a semiconductor substrate by epitaxial growth, the second p-type layer having an acceptor concentration higher than the first p-type layer: a step of activating acceptors of the first and second p-type layers: an implantation step of implanting impurity element ions for inactivating a part of the acceptors in the first p-type layer and the second p-type layer by a multi-stage ion implantation method into the first p-type layer and the second p-type layer in an electric field relaxation region surrounding an element area: and a step of forming an electrode on a surface of the second p-type layer in the element area.

According to the above other aspect, it is possible to set an optimum acceptor concentration for element performance in the element area for the first p-type layer and the second p-type layer that have epitaxially grown, and to improve the withstand voltage of the semiconductor equipment by forming a region with high resistance in the electric field relaxation region surrounding the element area by implanting impurity element ions that inactivate a part of the acceptors into the first p-type layer and the second p-type layer, thereby suppressing the formation of the electric field concentration point where the electric field is locally concentrated.

### Advantageous Effects of Invention

According to the present invention, it is possible to improve a withstand voltage of a semiconductor equipment.

### BRIEF DESCRIPTION OF DRAWINGS

FIG. 1 is a cross-sectional view showing a configuration of a semiconductor equipment according to an embodiment.

FIG. 2A is a part of a process diagram (part 1) of the semiconductor equipment according to the embodiment.

FIG. 2B is a part of the process diagram (part 1) of the semiconductor equipment according to the embodiment.

FIG. 2C is a part of the process diagram (part 1) of the semiconductor equipment according to the embodiment.

FIG. 3A is a part of a process diagram (part 2) of the semiconductor equipment according to the embodiment.

FIG. 3B is a part of the process diagram (part 2) of the semiconductor equipment according to the embodiment.

FIG. 3C is a part of the process diagram (part 2) of the semiconductor equipment according to the embodiment.

FIG. 4 is a diagram showing conditions for multi-stage ion implantation of the semiconductor equipment according to the embodiment.

FIG. 5 is a diagram showing a relationship between a withstand voltage of the semiconductor equipment according to the embodiment and a total dose of implanted boron.

FIG. 6 is a diagram showing the withstand voltage of the semiconductor equipment according to the embodiment, which is obtained by simulation.

FIG. 7A is a distribution diagram of equipotential surfaces when an avalanche occurs in a semiconductor equipment having an acceptor areal density of 1.0×10¹³ cm⁻².

FIG. 7B is a distribution diagram of equipotential surfaces when an avalanche occurs in a semiconductor equipment (without ion implantation) in which boron ions are not implanted into an electric field relaxation region.

FIG. 8A is a cross-sectional view showing a configuration of a semiconductor equipment of Example 1.

FIG. 8B is a plan view showing the configuration of the semiconductor equipment of Example 1.

FIG. 9 is a diagram showing conditions for multi-stage ion implantation of the semiconductor equipment of Example 1.

FIG. 10 is a cross-sectional view showing a configuration of a semiconductor equipment of Example 2.

FIG. 11 is a cross-sectional view showing a configuration of a semiconductor equipment of Example 3.

FIG. 12 is a diagram showing a withstand voltage of the semiconductor equipment of Example 3, which is obtained by simulation.

FIG. 13 is a cross-sectional view showing a configuration of a semiconductor equipment of Example 4.

FIG. 14 is a cross-sectional view showing a configuration of a semiconductor equipment of Example 5.

### DESCRIPTION OF EMBODIMENTS

Hereinafter, an embodiment of the present invention will be described based on the drawings. In addition, elements common to a plurality of drawings are denoted by the same reference numerals, and detailed descriptions of the elements will not be repeated.

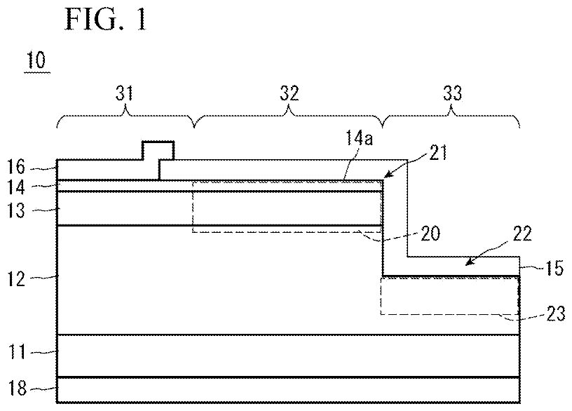

FIG. 1 is a cross-sectional view showing a configuration of a semiconductor equipment according to an embodiment. In the present embodiment, as the nitride semiconductor equipment, a gallium nitride vertical diode having a pn diode formed in an element area will be described as an example. For convenience of illustration, FIG. 1 shows an area from the element area to an isolation region at an end portion around the element area.

The element area, an electric field relaxation region, and the isolation region are divisions of regions in an in-plane direction of a semiconductor, and are bounded by a plane (line in a cross-sectional view shown in FIG. 1) perpendicular to a lamination direction.

For example, in a case where the semiconductor is viewed in a plan view, the element area is located in a central portion, the electric field relaxation region surrounding the element area is located around the element area, and the isolation region surrounding the electric field relaxation region is located around the electric field relaxation region.

Referring to FIG. 1, in the semiconductor equipment 10, an n-type layer 12, a first p-type layer 13, and a second p-type layer 14 are formed in this order on a semiconductor substrate 11. The n-type layer 12, the first p-type layer 13, and the second p-type layer 14 in an element area 31 extend up to at least an electric field relaxation region 32 in a horizontal direction. In the element area 31 and the electric field relaxation region 32 surrounding the element area 31, a protective film 15 is formed on the second p-type layer 14. The protective film 15 is formed outside the electric field relaxation region 32 and is formed on the n-type layer 12 in an isolation region 33 surrounding the electric field relaxation region 32. In the element area 31, an anode electrode 16 is formed on the second p-type layer 14 at an opening portion of the protective film 15. A cathode electrode 18 is formed on a back surface side of the gallium nitride semiconductor substrate 11.

The semiconductor substrate 11 is, for example, an n+ type having an impurity element concentration of 1× 10¹⁸ cm⁻³, and gallium nitride can be used. The gallium nitride semiconductor substrate 11 has a crystal structure of a wurtzite structure (hexagonal crystal), and a main surface is (0001) plane. The impurity element is, for example, silicon (Si).

The n-type layer 12 is a semiconductor crystal layer (gallium nitride) epitaxially grown on the semiconductor substrate 11 by a metal organic chemical vapor deposition method (MOCVD method) and has a thickness, for example, 10 μm. The n-type layer 12 contains an n-type impurity element, for example, silicon (Si), and has, for example, an impurity element concentration of 1.3×10¹⁶ cm⁻³.

The first p-type layer 13 is a semiconductor crystal layer (gallium nitride) epitaxially grown on the n-type layer 12 by the MOCVD method and has a thickness of, for example, 1.0 μm. The first p-type layer 13 contains a p-type impurity element, for example, magnesium (Mg), and has a concentration of, for example, 2×10¹⁸ cm⁻³ or less.

The second p-type layer 14 is a semiconductor crystal layer (gallium nitride) epitaxially grown on the first p-type layer 13 by the MOCVD method, and has a thickness of, for example, 50 nm. The second p-type layer 14 contains a p-type impurity element, for example, magnesium (Mg), and has a concentration of, for example, 1×10²⁰ cm⁻³ or more.

The element area 31 is located in a center of the pn diode and is a region in which an on-state current flows. In the element area 31, the anode electrode 16 is in ohmic contact with the second p-type layer 14. The anode electrode 16 may be a single metal film having a large work function, such as gold (Au), platinum (Pt), palladium (Pd), or nickel (Ni), or an alloy film thereof, and a laminated film of a gold (Au) film with a nickel (Ni) film as a base formed by a sputtering method is preferable.

In the electric field relaxation region 32, an impurity element implantation region 20 is formed in the second p-type layer 14 and the first p-type layer 13 in a depth direction from a surface of the second p-type layer 14. The impurity element implantation region 20 contains an impurity element that inactivates acceptors in the first p-type layer 13 and the second p-type layer 14. The impurity element preferably includes at least one element of boron (B), nitrogen (N), oxygen (O), phosphorus (P), zinc (Zn), and iron (Fe). Thus, active acceptor concentrations of the first p-type layer 13 and the second p-type layer 14 are reduced. It is preferable that the impurity element contains boron (B) in particular, from the viewpoint of electrical and thermal stability of withstand voltage characteristics. In the vicinity of a boundary between the first p-type layer 13 and the n-type layer 12, it is preferable to implant an impurity element such that an acceptor areal density of the first p-type layer 13 and a donor areal density of the n-type layer 12 immediately below are balanced. Thus, it can be easy to deplete the electric field relaxation region 32 when a reverse bias is applied to the pn diode, and electric field concentration on a mesa edge 21 of a boundary between the isolation region 33 and the electric field relaxation region 32 can be suppressed. As a result, the withstand voltage of the entire pn diode can be significantly improved.

The impurity element is implanted by an ion implantation method, and it is preferable to implant the impurity element by a multi-stage implantation method from the viewpoint that the impurity element concentration in the impurity element implantation region 20 can be made uniform. The impurity element implantation region 20 may be formed to reach the n-type layer 12 below the first p-type layer 13.

In the electric field relaxation region 32, the impurity element implantation region 20 may be formed such that a plurality of sub-regions having different impurity element concentrations are successively formed from a side close to the element area 31 to a side far from the element area 31 (for example, up to the mesa edge 21), and the impurity element concentration may be set larger in the sub-region on the side far from the element area 31 than the sub-region on the side close to the element area 31. Thus, an acceptor concentration on an outer peripheral side of the electric field relaxation region 32 can be made lower than that on an inner peripheral side of the electric field relaxation region 32, and the electric field concentration can be suppressed to further increase the withstand voltage. In addition, the number of the sub-regions may be two or three or more.

In addition, in the electric field relaxation region 32, the impurity element implantation region 20 may be formed such that a plurality of sub-regions are formed to surround the element area 31 from a side close to the element area 31 to a side far from the element area 31. Accordingly, by providing the impurity element implantation region to surround the element area 31 in a multiple manner in the electric field relaxation region 32, it is possible to reduce or avoid a risk of a local electric field concentration occurring due to an abnormality in shape of the semiconductor equipment caused by a manufacturing process.

In the isolation region 33, a mesa groove 22 is formed, and the n-type layer 12 from which the first p-type layer 13 and the second p-type layer 14 have been removed is formed. As a result, the first p-type layer 13 and the second p-type layer 14 of the semiconductor equipment 10 are electrically separated from the surroundings. In the mesa edge 21 at the boundary between the isolation region 33 and the electric field relaxation region 32, an angle between a surface 14a and a side surface of the second p-type layer 14 is shown as a right angle (90 degrees) in FIG. 1. This angle may be larger than 90 degrees (that is, an obtuse angle), and a cross-sectional shape of a mesa structure may be trapezoidal.

In a surface of the mesa groove 22, the semiconductor layer is the n-type layer 12. An impurity element implantation region 23 in which an impurity element is implanted to balance a areal density of the n-type impurity element in the vicinity of a surface of the n-type layer 12 may be formed from the surface of the n-type layer 12 to a predetermined depth. Thus, an active donor concentration in the n-type layer 12 is reduced. The impurity element to be implanted may be the same as the impurity element in the impurity element implantation region 20 in the electric field relaxation region 32.

As a modification example, an insulation region in which the acceptors of the first p-type layer 13 and the second p-type layer 14 are inactivated may be formed in the isolation region without forming the mesa groove 22. Thus, a dry etching process when forming the mesa groove 22 is unnecessary, and damage to the crystal layer (the first p-type layer 13 and the second p-type layer 14) that tends to occur around the mesa edge 21 can be avoided, thereby suppressing the electric field concentration caused by such a manufacturing process.

The protective film 15 is formed on the surface of the second p-type layer 14 or the n-type layer 12 in the electric field relaxation region 32 and the isolation region 33 from an outer periphery of the anode electrode 16 in the element area 31. The protective film 15 is made of an insulating material and has, for example, a thickness of 1.0 μm. As the protective film 15, a SiO₂ film, a SiN film, or an Al₂O₃ film can be used. It is preferable to form the SiO₂ film by a CVD method, the SiN film by a plasma CVD method, and the Al₂O₃ film by an atomic layer deposition (ALD) method.

The cathode electrode 18 is formed on a back surface of the semiconductor substrate 11. The cathode electrode 18 is preferable in that a laminated film of an aluminum (Al) film with a titanium (Ti) film as a base can form ohmic contact with the semiconductor substrate 11. The cathode electrode 18 may be a laminated film having three or more layers, on which another metal is further laminated.

According to the present embodiment, in the electric field relaxation region 32 surrounding the element area 31, the impurity element implantation region 20 in which the impurity element that inactivates the acceptors is contained in the first p-type layer 13 and the second p-type layer 14 is formed. Since a part of the acceptor of the impurity element implantation region 20 is inactivated to increase the resistance, formation of an electric field concentration point where the electric field is locally concentrated is suppressed, and the withstand voltage of the semiconductor equipment 10 can be improved. Furthermore, in the isolation region 33 surrounding the electric field relaxation region 32, by forming the mesa groove 22 in which the n-type layer 12 is exposed by removing the first p-type layer 13 and the second p-type layer 14, the electric field concentration can be further suppressed, and the withstand voltage of the semiconductor equipment 10 can be further improved.

In the present embodiment, the p-type layer has a two-layer structure of the first p-type layer 13 and the second p-type layer 14, but may have a one-layer structure in which the acceptor concentration is the same as that of the second p-type layer 14.

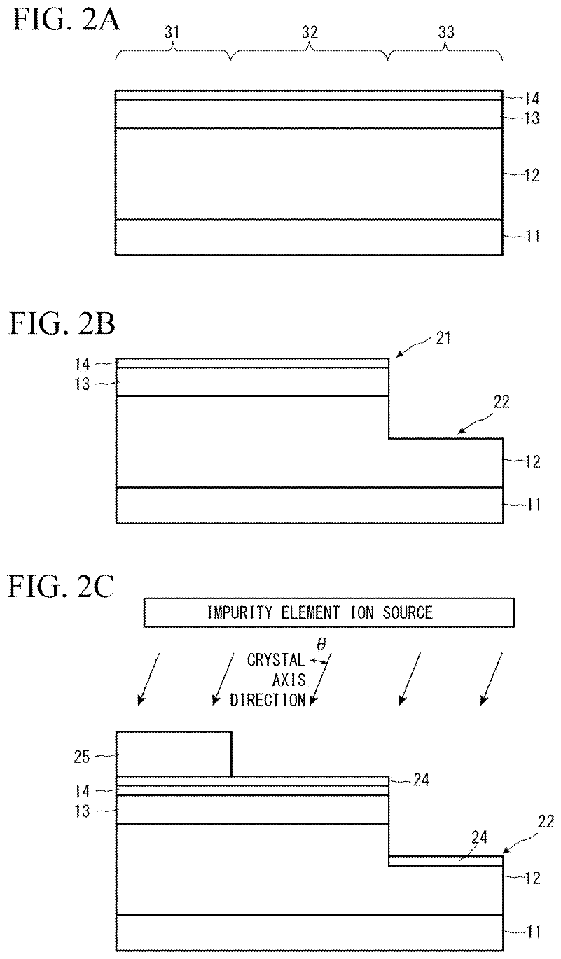

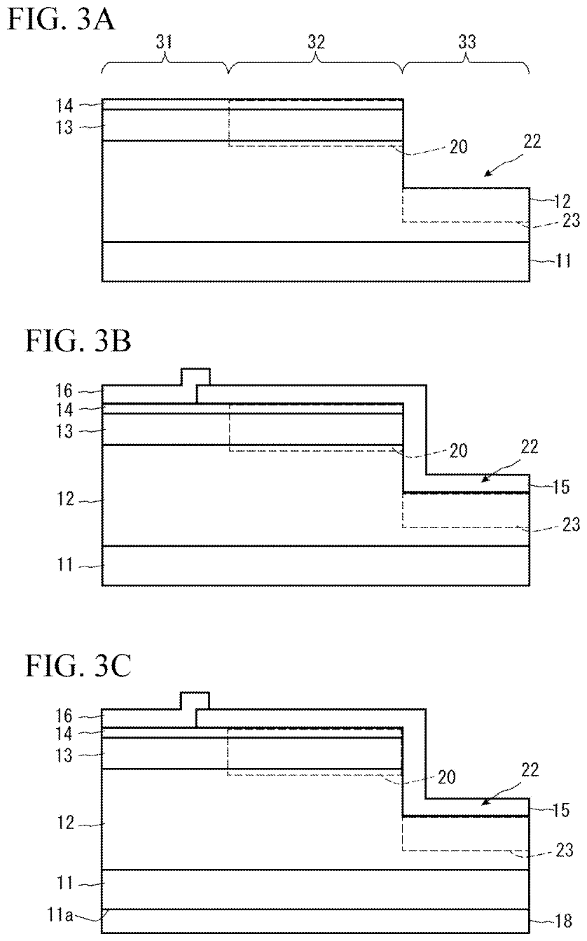

FIGS. 2A to 2C and FIGS. 3A to 3C are process diagrams (part 1 and part 2) of the semiconductor equipment according to an embodiment. A manufacturing method for the semiconductor equipment will be described with reference to FIGS. 2A to 2C and FIGS. 3A to 3C.

In the process of FIG. 2A, the n-type layer 12, the first p-type layer 13, and the second p-type layer 14 are sequentially formed on the semiconductor substrate 11. Specifically, the n-type layer 12, the first p-type layer 13, and the second p-type layer 14 are sequentially epitaxially grown on the n+ type gallium nitride semiconductor substrate 11 having an impurity element concentration of 1×10¹⁸ cm⁻³ by the MOCVD method. The semiconductor substrate laminated in this way may be used. Next, a heat treatment is performed in a nitrogen gas atmosphere to activate the acceptor impurity elements of the first p-type layer 13 and the second p-type layer 14. The conditions for the heat treatment are, for example, 800° C. for 30 minutes, but the heat treatment may be performed under other conditions.

Next, in the process of FIG. 2B, the first p-type layer 13 and the second p-type layer 14 in the isolation region 33 are removed to expose the n-type layer 12 and the mesa groove 22 is formed. Specifically, a SiO₂ film having a thickness of 1.0 μm is formed on the entire surface of the second p-type layer 14 by the CVD method. Next, a resist mask is formed on the SiO₂ film by a photolithography method, the SiO₂ film in the isolation region 33 is removed by wet etching to expose the second p-type layer 14, and the second p-type layer 14, the first p-type layer 13, and the n-type layer 12 are removed by dry etching, for example, a reactive ion etching method (RIE method) to expose the n-type layer 12. The mesa groove 22 is formed, for example, to a depth of 2.5 μm from the surface of the second p-type layer 14, for example. Next, the SiO₂ film on the surface of the second p-type layer 14 is removed.

Next, in the process of FIG. 2C, impurity element ions that inactivate a part of the acceptors is implanted into the second p-type layer 14, the first p-type layer 13, and the n-type layer 12 in the electric field relaxation region 32, and the n-type layer 12 in the isolation region 33 to form the impurity element implantation region 20 and the impurity element implantation region 23. Specifically, the SiO₂ film 24 is formed as a through film for the ion implantation method by the CVD method on the surface of the second p-type layer 14 in the element area 31 and the electric field relaxation region 32, and on the surface of the n-type layer 12 in the isolation region 33. The SiO₂ film 24 has a thickness of, for example, 50 nm. A photoresist film 25 is formed on the SiO₂ film 24 in the element area 31 to serve as a mask. Next, impurity element ions are implanted into the electric field relaxation region 32 and the isolation region 33 from an impurity element ion source by the multi-stage ion implantation method. The impurity element ions preferably include ions of at least one element of boron (B), nitrogen (N), oxygen (O), phosphorus (P), zinc (Zn), and iron (Fe), and in particular, it is preferable to include boron (B) from the viewpoint of electrical and thermal stability of withstand voltage characteristics. An ion implantation angle is preferably tilted with respect to a c-axis of a crystal axis of the second p-type layer 14, the first p-type layer 13, and the n-type layer 12 (that is, a c-axis of a crystal axis of the semiconductor substrate 11), preferably in a range of 4° or more and 7° or less. Thus, ion channeling along the crystal axis can be suppressed.

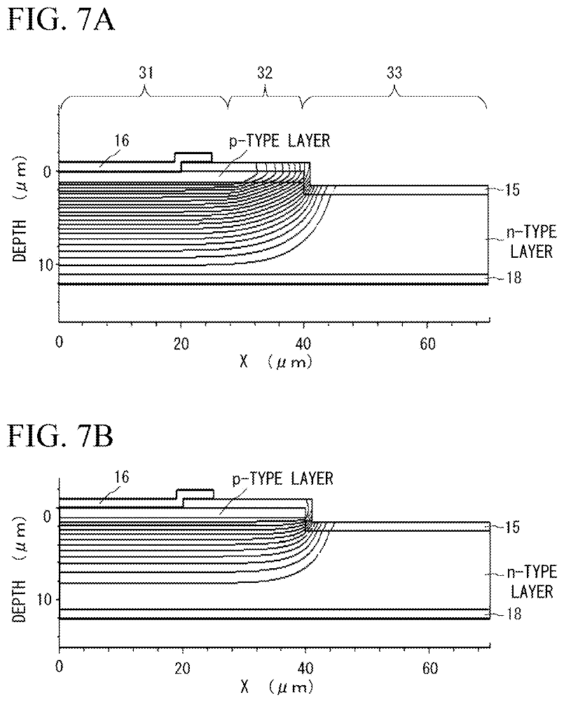

In the ion implantation of the present embodiment, a multi-stage implantation method in which implantation is performed by changing implantation energy and dosage for each time of implantation is used, and in order to control a depth distribution of the impurity element concentration, it is preferable to divide the implantation into three or more times. In addition, it is preferable to perform the implantation using the highest implantation energy at the beginning and gradually decrease the implantation energy each time from the viewpoint of improving the controllability of the depth distribution. The maximum implantation energy is preferably set such that the implanted impurity element reaches the entire p-type layer, and is set to, for example, 400 keV in the present embodiment with a p-type layer thickness of 1 μm. It is preferable to set a total dose of the multi-stage ion implantation such that the acceptor areal density of the first p-type layer 13 is around 1×10¹³ cm⁻² from the viewpoint of suppressing the electric field concentration in the electric field relaxation region 32 (see FIGS. 6 and 7 described later), and set to, for example, 1×10¹³ cm⁻² in the present embodiment.

By the process described with reference to FIG. 2C, as shown in FIG. 3A, in the electric field relaxation region 32, the impurity element implantation region 20 is formed from the second p-type layer 14, the first p-type layer 13, and the surface of the n-type layer 12 (interface with the first p-type layer 13) to a predetermined depth in the depth direction from the surface of the second p-type layer 14. In the isolation region 33, the impurity element implantation region 23 is formed from the surface of the n-type layer 12 to a predetermined depth. Further, in the process of FIG. 3A, the photoresist film 25 is removed and a heat treatment is performed in a nitrogen gas atmosphere to stabilize characteristics of the impurity element implantation regions 20 and 23. The conditions for the heat treatment are, for example, 800° ° C. for 30 minutes, but the heat treatment may be performed under other conditions. Furthermore, the SiO₂ film 24 is removed by wet etching.

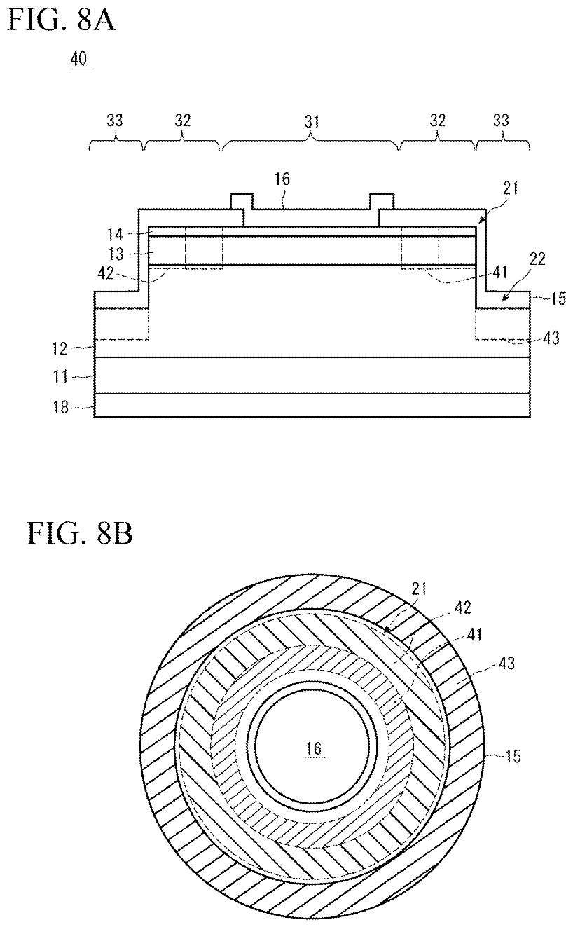

In addition, in the process of FIG. 2C, the multi-stage ion implantation may also be performed on the surface of the second p-type layer 14 in the electric field relaxation region 32 by forming the photoresist film 25 to surround the element area 31 with a plurality of photoresist films annularly spaced apart from each other in plan view. Thus, sub-regions in which a plurality of impurity elements are implanted are formed from the second p-type layer 14, the first p-type layer 13, and the surface of the n-type layer 12 (interface with the first p-type layer 13) to a predetermined depth in the depth direction from the surface of the second p-type layer 14 such that the impurity element implantation region surrounds the element area 31 in the electric field relaxation region 32 from a side close to the element area 31 to a side far from the element area 31 (see Example 1 and FIG. 8 described later).

Further, after the process of FIG. 2C, in the impurity element implantation region 20 of the electric field relaxation region 32, impurity element ions may be further implanted in a portion far from the element area 31 by the multi-stage ion implantation method to form a sub-region having a higher areal density of the impurity elements than that of the impurity element implantation region 20 close to the element area 31 (see Example 2 and FIG. 10 described later).

Next, in the process of FIG. 3B, the protective film 15 that covers the surface of the second p-type layer 14 in the element area 31 and the electric field relaxation region 32 and the surface of the n-type layer 12 in the isolation region 33 is formed, and then the anode electrode 16 is formed by opening the protective film 15 in the element area 31. Specifically, the protective film 15, for example, a SiO₂ film (thickness 1 μm) is formed on the entire surface shown in FIG. 3A by the CVD method. Next, the resist mask is formed on the protective film 15 by a photolithography method, and the protective film 15 of a portion for forming the anode electrode 16 is removed by wet etching to form an opening portion having, for example, a diameter of 200 μm for exposing the second p-type layer 14. Next, a metal layer that covers the exposed second p-type layer 14 and the protective film 15, for example, a nickel (Ni) film is formed to a thickness of 100 nm by a vapor deposition method. Next, a resist mask is formed by a photolithography method, and an unnecessary metal layer on the protective film 15 is removed by wet etching to form the anode electrode 16.

Next, in the process of FIG. 3C, the cathode electrode 18 is formed on a back surface 11a of the semiconductor substrate 11. Specifically, cleaning is performed after removing an oxide film on the back surface 11a of the semiconductor substrate 11, and a metal laminate film, for example, a titanium (Ti) film, an aluminum (Al) film, and a titanium nitride (TiN) film are deposited in order from the surface of the back surface 11a by a sputtering method or a vapor deposition method on the entire back surface 11a to form the cathode electrode 18. Next, a heat treatment is performed in a nitrogen gas atmosphere to reduce contact resistance of the anode electrode 16 and the cathode electrode 18. The conditions for the heat treatment are, for example, 550° ° C. for 10 minutes. In this way, the semiconductor equipment 10 is formed.

According to the manufacturing method for the semiconductor equipment of the present embodiment, it is possible to set an optimum acceptor concentration for element performance in the element area 31 for the first p-type layer 13 and the second p-type layer 14 that have epitaxially grown, and to improve the withstand voltage of the semiconductor equipment 10 by forming the impurity element implantation region 20 with high resistance in the electric field relaxation region 32 surrounding the element area 31 by implanting impurity element ions that inactivate a part of the acceptors into the first p-type layer 13 and the second p-type layer 14, thereby suppressing the formation of the electric field concentration point where the electric field is locally concentrated. Furthermore, in the isolation region 33 surrounding the electric field relaxation region 32, by forming the mesa groove 22 in which the n-type layer 12 is exposed by removing the first p-type layer 13 and the second p-type layer 14, the electric field concentration can be further suppressed, and the withstand voltage of the semiconductor equipment 10 can be further improved.

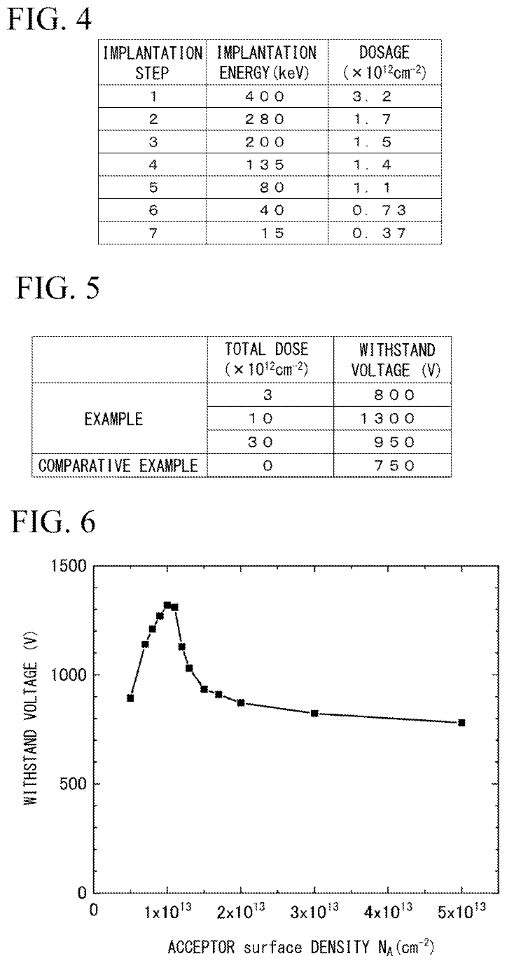

FIG. 4 is a diagram showing conditions for the multi-stage ion implantation of the semiconductor equipment according to the embodiment, and shows an example of the conditions for the multi-stage ion implantation in the process of FIG. 2C. Using boron ions as an example, conditions have been found in which the areal density of impurity elements in the depth direction of the gallium nitride semiconductor substrate becomes substantially uniform by implanting boron ions in multiple stages while changing the implantation energy and dosage.

Specifically, as shown in FIG. 2C, a SiO₂ film (thickness 50 nm) for protection was formed on the surface of the gallium nitride semiconductor substrate, and a resist mask having a thickness of 3 μm was formed on the SiO₂ film. Referring to FIG. 4, ion implantation was performed in seven stages. First, a dosage of 3.2×10¹² cm⁻² was implanted at 400 keV, which is the maximum implantation energy, and the implantation energy was sequentially decreased to make the total dose of 1.0×10¹³ cm⁻². After the ion implantation, a heat treatment was performed at 800° ° C. for 30 minutes in a nitrogen gas atmosphere while the SiO₂ film was deposited. When a profile of boron in the depth direction was acquired by a secondary ion mass spectrometry (SIMS analysis method), it was found that the boron was distributed at a uniform concentration up to a depth of 0.7 μm, and the boron was distributed up to a depth of at least 1.5 μm while the concentration was gradually decreased with depth in deeper portions. As a result, it was confirmed that the boron was distributed throughout the second p-type layer 14 and the first p-type layer 13 and reached the n-type layer 12 in the depth direction from the surface of the second p-type layer 14.

FIG. 5 is a diagram showing a relationship between the withstand voltage of the semiconductor equipment according to the embodiment and the total dose of implanted boron, and the withstand voltage of the pn diode of the semiconductor equipment 10 according to the present embodiment was measured with respect to the total dose.

Referring to FIG. 5, it was found that the pn diode with a total dose of boron ions of 3×10¹² cm⁻² to 3×10¹³ cm⁻² had the maximum withstand voltage of 1300 V, and the withstand voltage was higher by 100 V to 600 V than a case without the boron ion implantation as a comparative example. As a result, it was possible to confirm the effect of improving the withstand voltage by implanting impurity element ions into the semiconductor equipment 10 to form the impurity element implantation region 20.

FIG. 6 is a diagram showing the withstand voltage of the semiconductor equipment according to the embodiment, which is obtained by simulation. A layer configuration of the semiconductor equipment 10 having a mesa structure shown in FIG. 1 was simplified, the n-type layer was formed with a thickness of 10 μm and a donor concentration of 0.8×10¹⁶ cm⁻³, the first p-type layer 13 and the second p-type layer 14 were formed as one p-type layer with a thickness of 1 μm and an acceptor concentration of 2×10¹⁸ cm⁻³, and simulation was performed to obtain the withstand voltage in a range of 0.5×10¹³ cm⁻² to 5×10¹³ cm⁻² assuming that the acceptor areal density was N_{A} cm⁻² by multi-stage ion implantation of boron ions in the impurity element implantation region 20 of the electric field relaxation region 32. In the simulation, a Poisson equation was numerically solved for a two-dimensional model structure corresponding to the above-described structure, and the withstand voltage was calculated by applying an impact ionization coefficient in the document (IEDM, T. Maeda et. al, Tech. Dig. 2019, pp. 4.2.1 to 4.2.4).

Referring to FIG. 6, the withstand voltage increases from 900 V as the acceptor areal density increases from 0.5×10¹³ cm⁻², and the withstand voltage showed the maximum value of 1320 V at 1.0×10¹³ cm⁻². When the acceptor areal density was further increased, the withstand voltage gradually decreased and remained almost constant. The relationship between the withstand voltage and the acceptor areal density corresponds to the measurement result shown in FIG. 5. The maximum value of the withstand voltage obtained by the simulation is close to the withstand voltage of 1320 V in the measurement result shown in FIG. 5. It was found that the acceptor areal density (1.0×10¹³ cm⁻²) showing the maximum value of the withstand voltage is close to the donor areal density 0.8×10¹³ cm⁻² of the n-type layer, and is a condition that the acceptor areal density in the impurity element implantation region is almost the same as the donor areal density of the n-type layer.

FIGS. 7A and 7B are distribution diagrams of equipotential surfaces when an avalanche occurs in the semiconductor equipment. FIG. 7A is a distribution diagram of equipotential surfaces when the semiconductor equipment having an acceptor areal density of 1.0×10¹³ cm⁻² shows a withstand voltage of 1320 V as shown in FIG. 6. FIG. 7B is a distribution diagram of equipotential surfaces when a withstand voltage of 750 V is shown as an example in which boron ions are not implanted, that is, as an example in which boron is not implanted into the electric field relaxation region 32. FIGS. 7A and 7B are obtained by simulation. These figures show potential distributions at the moment when applied voltages of the cathode electrode 18 and the anode electrode 16 reach the withstand voltage and an avalanche current starts to flow. A horizontal axis is a distance X (μm) from a center of the pn diode, and a vertical axis is a depth from the surface of the second p-type layer 14. For convenience of illustration, the first p-type layer 13 and the second p-type layer 14 are shown as one layer, and the semiconductor substrate 11 and the n-type layer 12 are shown as one layer. The equipotential surfaces of FIGS. 7A and 7B are shown every 70V.

Reference to FIG. 7A, it can be seen that in the semiconductor equipment having an acceptor areal density of 1.0×10¹³ cm⁻², the equipotential surfaces on the surface of the p-type layer in the electric field relaxation region 32 are equally spaced in a direction of the isolation region 33 and the electric field concentration is suppressed. It is considered that the distribution of the equipotential surfaces is close to a distribution in a case where the total dose is optimized in the electric field relaxation region 32 and the withstand voltage is maximized.

On the other hand, referring to FIG. 7B, it can be seen that in an example in which the boron ions are not implanted into the electric field relaxation region 32, the equipotential surface does not appear on the surface of the p-type layer in the electric field relaxation region 32, and the equipotential surface narrows near the mesa edge, resulting in the electric field concentration. Therefore, it is considered that the withstand voltage is decreased to 750 V.

According to the above simulation results of FIG. 6 and FIGS. 7A and 7B, it was possible to confirm a mechanism in which by the boron implantation of the p-type layer in the electric field relaxation region 32, the acceptor concentration (and the acceptor areal density) of the p-type layer is reduced, and a withstand voltage of a pn terminal structure is improved.

### Example 1

The semiconductor equipment of Example 1 is a vertical pn diode element, and specifically, is different in a structure of the impurity element implantation region in the electric field relaxation region from the semiconductor equipment according to the embodiment shown in FIG. 1.

FIGS. 8A and 8B are views showing a configuration of a semiconductor equipment of Example 1. FIG. 8A is a cross-sectional view, and FIG. 8B is a plan view. In FIG. 8B, a range of an impurity element implantation region of a gallium nitride semiconductor layer below a protective film is indicated by a broken line. Referring to FIGS. 8A and 8B, in the semiconductor equipment of Example 1, the pn diode is formed in the element area 31, and in a central portion of the element area 31 in a plan view, the anode electrode 16 having a diameter of 200 μm, which is in ohmic contact with the second p-type layer 14, is formed. The cathode electrode 18 is formed on the back surface of the semiconductor substrate 11. The semiconductor substrate 11 is a gallium nitride substrate with a Ga (0001) plane on a surface side and a thickness of 350 μm and is an n+ crystal doped with Si. The Si concentration is 1×10¹⁸ cm⁻³, but may be higher than that.

On the semiconductor substrate 11, the n-type layer 12, the first p-type layer 13, and the second p-type layer 14 are formed in this order, which are gallium nitride formed by epitaxial growth by the MOCVD method. The n-type layer 12 has a thickness of 10 μm and is doped with Si. The Si concentration is 1.2×10¹⁶ cm⁻³. With this Si concentration, a withstand voltage exceeding 1300 V can be obtained. By setting the thickness of the n-type layer 12 to 10 μm or more and the Si concentration to be lower than 1.2×10¹⁶ cm⁻³, a higher withstand voltage can be obtained.

The first p-type layer 13 has a thickness of 1 μm and is doped with Mg. The Mg concentration is 1.5×10¹⁸ cm⁻³. Although this thickness and Mg concentration are still functionally effective, in a case where the first p-type layer 13 can be epitaxially grown by sufficiently controlling the Mg concentration, it is preferable that the Mg concentration is lower, specifically the Mg concentration is set to 1×10¹⁸ cm⁻³ or less from the viewpoint that the electric field relaxation in the electric field relaxation region 32 becomes significant.

The second p-type layer 14 has a thickness of 50 nm and is doped with Mg. The Mg concentration is 1×10²⁰ cm⁻³. Other conditions than this thickness and Mg concentration are also applicable as long as ohmic resistance with the anode electrode 16 is low.

The anode electrode 16 is a laminated film in which a Ni film and an Au film are laminated on the second p-type layer 14 by a sputtering method. Thus, the anode electrode 16 can make ohmic contact with the second p-type layer 14. The cathode electrode 18 is a laminated film in which a Ti film and an Al film are laminated on the back surface of the gallium nitride semiconductor substrate 11.

In the electric field relaxation region 32 surrounding the element area 31 of Example 1, boron ions are implanted into the second p-type layer 14 and the first p-type layer 13 in the depth direction from at least the surface of the second p-type layer 14, and an inner implantation area 41 close to the element area 31 and an outer implantation area 42 far from the element area 31 having different boron concentrations are formed. The total dose of boron is larger in the outer implantation area 42 than in the inner implantation area 41 and is set to 3×10¹² cm⁻² and 1×10¹³ cm⁻² in the inner and outer implantation areas. In detail, the distributions of the boron concentrations in the inner implantation area 41 and the outer implantation area 42 in the depth direction are almost uniform from the surface of the second p-type layer 14 to a bottom surface of the first p-type layer 13 (interface between the first p-type layer 13 and the n-type layer 12), and decrease sharply from the interface to the inside of the n-type layer 12.

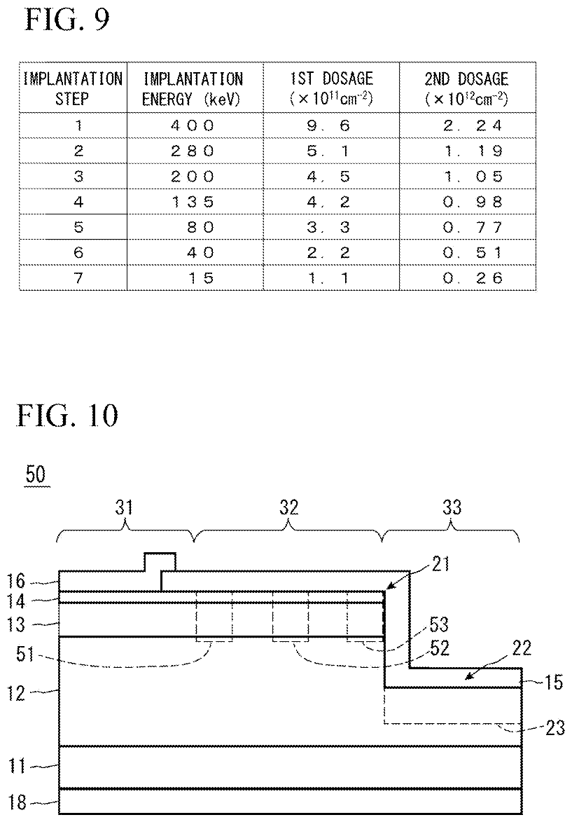

FIG. 9 is a diagram showing conditions for multi-stage ion implantation of the semiconductor equipment of Example 1. Referring to FIG. 9 in conjunction with FIG. 8, the multi-stage implantation of boron ions is performed according to the method and conditions described with respect to FIG. 2C. However, with the first multi-stage ion implantation, the boron ions are implanted into the inner implantation area 41, the outer implantation area 42, and an impurity element implantation region 43 in the isolation region 33 such that the total dose is 3×10¹² cm⁻². Further, the surfaces of the element area 31 and the inner implantation area 41 are newly covered with a resist film having a thickness of 3 μm and with the second multi-stage ion implantation, the boron ions are implanted into the outer implantation area 42 and the impurity element implantation region 43 in the isolation region 33 such that the total dose is 7×10¹² cm⁻². The final total dose, which is the sum of the first ion implantation and second ion implantation into the above regions, is 1×10¹³ cm⁻².

A width of each of main surfaces of the inner implantation area 41 and the outer implantation area 42 in an in-plane direction is 10 μm. It is preferable that the width of each of the inner implantation area 41 and the outer implantation area 42 is longer, and it is preferable that the width is 10 μm or more and 50 μm or less from the viewpoint that the electric field relaxation can be performed more reliably.

In the isolation region 33, the mesa groove 22 from which an entirety of the first p-type layer 13 and the second p-type layer 14 is removed is formed, and the n-type layer 12 is exposed on a surface of the mesa groove 22. The boron ions are implanted into the n-type layer 12 to form the impurity element implantation region 43. The boron concentration in the impurity element implantation region 43 is 7×10¹² cm⁻². The mesa groove 22 has a depth of 2.5 μm. The depth of the mesa groove 22 may be any depth at which the first p-type layer 13 and the second p-type layer 14 are completely removed, and a deeper one is preferable from the viewpoint of electric field relaxation. The width of the mesa groove 22 is 20 μm, but is preferably 50 μm or more from the viewpoint of electric field relaxation.

The protective film 15 covers a surface of a gallium nitride crystal layer. Specifically, the protective film 15 covers the surface of the second p-type layer 14 and the surface of the n-type layer 12 other than the anode electrode 16. The protective film 15 is a SiO₂ film having a thickness of 1 μm-formed by a CVD method.

In FIG. 8, a shape of the mesa structure in plan view is circular, but it may be oval or hexagonal, and any shape can be applied.

### Example 2

A semiconductor equipment of Example 2 is a vertical pn diode element, which has a different terminal structure from that of the vertical pn diode element of Example 1. Specifically, a structure of the impurity element implantation region in the electric field relaxation region is different, and other configurations are the same as Example 1.

FIG. 10 is a cross-sectional view showing a configuration of the semiconductor equipment of Example 2. Reference to FIG. 10, in the semiconductor equipment 50 of Example 2, in the electric field relaxation region 32, impurity element implantation regions 51 to 53 into which boron is implanted are formed to surround the element area 31. In the semiconductor equipment 50, the impurity element implantation regions 51 to 53 are annularly formed in plan view.

In the impurity element implantation regions 51 to 53, boron ions are implanted into the second p-type layer 14 and the first p-type layer 13 in the depth direction from at least the surface of the second p-type layer 14 by multi-stage ion implantation. In each of the impurity element implantation regions 51 to 53, the total dose is set to 1×10¹³ cm⁻². In detail, the distributions of the boron concentrations in the impurity element implantation regions 51 to 53 in the depth direction are almost uniform from the surface of the second p-type layer 14 to a bottom surface of the first p-type layer 13 (interface between the first p-type layer 13 and the n-type layer 12), and decrease sharply from the interface to the inside of the n-type layer 12.

A width of each of main surfaces of the impurity element implantation regions 51 to 53 in an in-plane direction is 10 μm. It is preferable that the width of each of the impurity element implantation regions 51 to 53 is 5 μm or more and 50 μm or less from the viewpoint that the electric field relaxation can be performed more reliably. The widths of the impurity element implantation regions 51 to 53 may be different from each other. By providing the impurity element implantation regions 51 to 53 to surround the element area 31 in a multiple manner in the electric field relaxation region 32, an effect can be exhibited to reduce or avoid a risk of a local electric field concentration occurring due to an abnormality in shape of the semiconductor equipment 50 caused by a manufacturing process. In Example 2, three impurity element implantation regions 51 to 53 are provided, but the impurity element implantation regions may be two, or four or more.

### Example 3

A semiconductor equipment of Example 3 is a vertical pn diode element, which has a different terminal structure from that of the vertical pn diode element of Examples 1 and 2, and is the same as the embodiment except that, specifically, a structure of the impurity element implantation region in the electric field relaxation region is different.

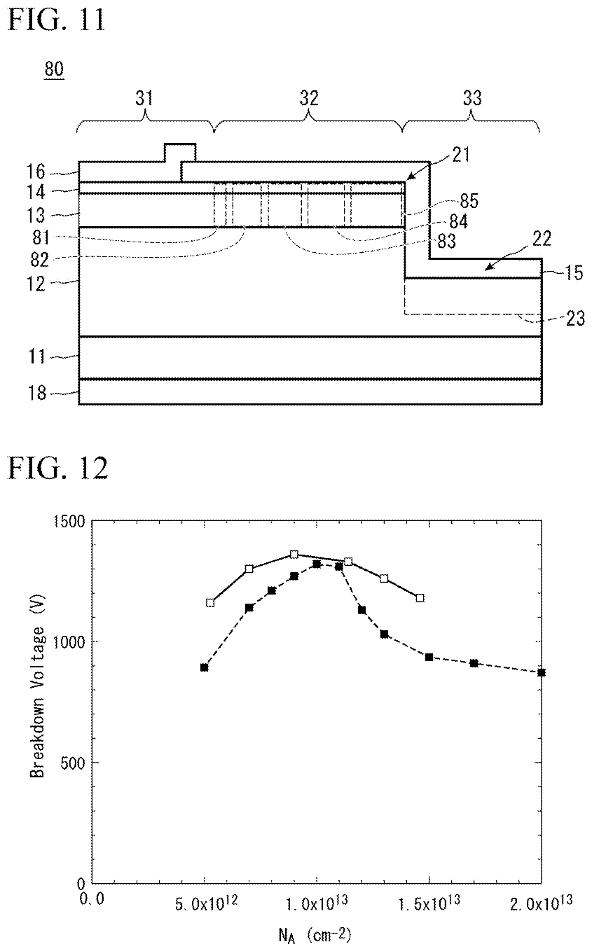

FIG. 11 is a cross-sectional view showing a configuration of the semiconductor equipment of Example 3. Reference to FIG. 11, in the semiconductor equipment 80 of Example 3, in the electric field relaxation region 32, impurity element implantation regions 81 to 85 into which boron is implanted are formed to annularly surround the element area 31.

In the impurity element implantation regions 81 to 85, boron ions are implanted into the second p-type layer 14 and the first p-type layer 13 in the depth direction from at least the surface of the second p-type layer 14 by multi-stage ion implantation under the same conditions as the embodiment. In the resist mask used for this ion implantation, four parallel rows of mask regions are annularly patterned in a region corresponding to the electric field relaxation region 32, and the impurity element implantation regions 81 to 85 separated from each other are formed. In the example of FIG. 11, mask regions each having a width of 2 μm are disposed at positions of 6 μm, 5 μm, 4 μm, and 3 μm with respect to the mesa edge 21, and the width of each impurity element implantation region is designed to decrease in order from an outer side to an inner side. The dosage of boron ions in the impurity element implantation regions 81 to 85 is 1×10¹³ cm⁻² as in the embodiment, and the dosage of boron ions in the mask region sandwiched between the implantation regions is smaller than this. Therefore, an effective boron concentration is higher on an outer side of the electric field relaxation region 32 because the mask regions are more sparsely arranged, and an effective boron concentration is lower on an inner side of the electric field relaxation region 32 because the mask regions are more densely arranged. A magnitude relationship of the boron concentration depending on the position in the electric field relaxation region is similar to that of Example 1, except that the boron concentration gradually changes in this example. Therefore, when the reverse bias is applied, the depletion layer spread in the electric field relaxation region 32 becomes larger, and the electric field relaxation becomes more effective.

That is, in the semiconductor equipment of this example, widths of the plurality of sub-regions become wider from the side close to the element area toward the side far from the element area.

The width of the impurity implantation region 85 (sub-region) located farthest from the element area among the impurity implantation regions 81 to 85 (a plurality of sub-regions) may be 1.5 μm to 8 μm, preferably 1.5 μm to 5 μm, and more preferably 1.5 μm to 3 μm.

The width of the impurity implantation region 85 farthest from the element area may be 1.5 to 4 times, preferably 1.5 to 3 times, and more preferably 1.5 to 2 times the width of the impurity implantation region 81 closest to the element area.

The intervals between the impurity implantation regions 81 to 85 may be the same or different. Parts of the plurality of intervals may be the same, and other parts may be different.

Next, the configuration of the semiconductor equipment X having a mesa structure shown in FIG. 11 was simplified, and the withstand voltage was obtained by simulation in the same manner as in the embodiment. In the same manner as in the embodiment, the n-type layer was formed to have a thickness of 10 μm and a donor concentration of 0.8×10¹⁶ cm⁻³, and the first p-type layer 13 and the second p-type layer 14 were formed to have a thickness of 1 μm and an acceptor concentration of 10¹⁸ cm⁻³ as one p-type layer. By the multi-stage ion implantation of boron ions, the acceptor areal density of the impurity element implantation region was varied in a range of 0.3×10¹³ cm⁻² to 1.5×10¹³ cm⁻², and it was assumed that a p-type region having an acceptor areal density N_{A}=2.5×10¹³ cm⁻² and a width of 1 μm was left in the mask region sandwiched between the impurity element implantation regions. FIG. 12 is a result of plotting the withstand voltage calculated for the two-dimensional model structure with the average acceptor areal density (N_{A}) of the electric field relaxation region 32 as a function. In a solid line showing this example, the maximum value of the withstand voltage increases to 1360 V and the N_{A} dependence of the withstand voltage becomes smaller with respect to a dotted line showing the result of the embodiment. This means that the withstand voltage does not easily change even when the acceptor concentration or thickness of the first p-type layer 13 and the dosage of boron ion implantation are varied, and a process margin can be expanded when applied to manufacturing.

Since this example can be realized only by changing a mask layout without changing the process described in the embodiment, there is a great advantage in practical use. In this example, five impurity element implantation regions are provided, and numerical examples of the width and the interval are shown. However, the number of the impurity element implantation regions may be four or less, or six or more, and more preferably ten or more. The width and the interval are also not limited to the example of FIG. 11.

### Example 4

The semiconductor equipment of Example 4 is a vertical pn diode element, and is a modification example of the semiconductor equipment 10 according to the embodiment shown in FIG. 1. In the semiconductor equipment 10, the mesa groove 22 is formed by removing the first p-type layer 13 and the second p-type layer 14 in the isolation region 33. In the semiconductor equipment of Example 4, the first p-type layer 13 and the second p-type layer 14 are insulated without forming the mesa groove.

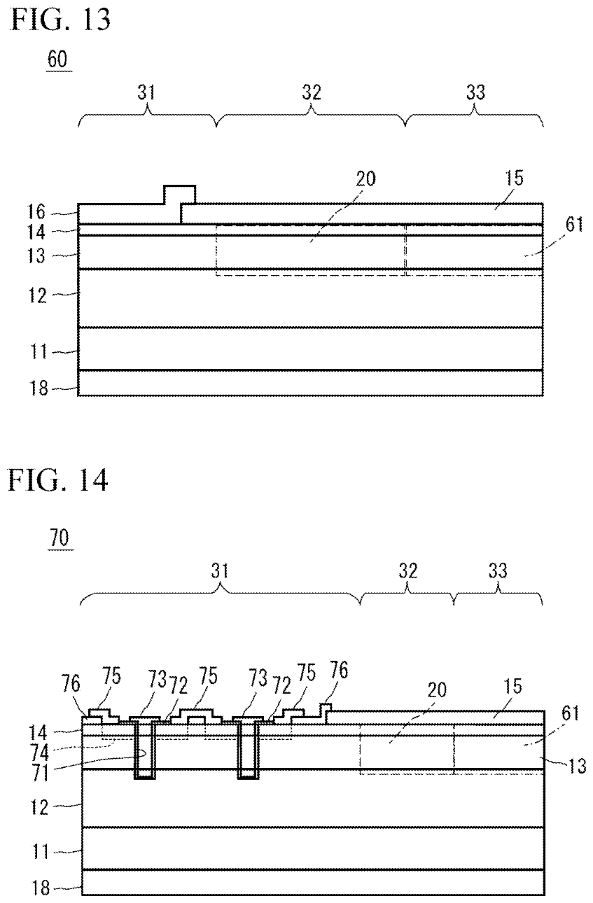

FIG. 13 is a cross-sectional view showing a configuration of the semiconductor equipment of Example 4. Referring to FIG. 13, in the semiconductor equipment 60 of Example 4, in the isolation region 33, an impurity element implantation region 61 is formed from the surface of the second p-type layer 14 of gallium nitride to the second p-type layer 14 and a depth of a bottom portion of the first p-type layer 13. In the impurity element implantation region 61, the boron ions are implanted by multi-stage ion implantation in which the maximum implantation energy is set to 400 keV such that boron is distributed from the surface of the second p-type layer 14 to the bottom portion of the first p-type layer 13. Thus, portions of the second p-type layer 14 and the first p-type layer 13 can be sufficiently insulated, and the impurity element implantation region 61 of an i-type layer can be formed.

In the impurity element implantation region 20 of the electric field relaxation region 32, the total dose is set to 1×10¹³ cm⁻². On the other hand, in the impurity element implantation region 61 of the isolation region 33, the total dose is set to 5×10¹⁴ cm⁻², but it is preferable to set the total dose to 3×10¹⁴ cm⁻² to 3×10¹⁵ cm⁻² from the viewpoint that the electric field concentration can be suppressed.

According to Example 4, the dry etching process of forming the mesa groove 22 of the semiconductor equipment according to the embodiment shown in FIG. 2B becomes unnecessary. Accordingly, it is possible to avoid damage to a surface portion of the gallium nitride crystal layer that tends to occur around the mesa edge 21 and to suppress the electric field concentration caused by such a manufacturing process. Accordingly, the semiconductor equipment 60 of Example 4 can further effectively improve the withstand voltage in addition to the effect of improving the withstand voltage in the impurity element implantation region 20 in the electric field relaxation region 32 of the semiconductor equipment 10 according to the embodiment shown in FIG. 1.

### Example 5

The semiconductor equipment of Example 5 is a semiconductor equipment in which a trench MOS transistor is formed in the element area, and the electric field relaxation region and the isolation region are formed in the same manner as in Example 4 shown in FIG. 13.

FIG. 14 is a cross-sectional view showing a configuration of the semiconductor equipment of Example 5. Referring to FIG. 14, in the semiconductor equipment 70, the n-type layer 12, the first p-type layer 13, and the second p-type layer 14, which are gallium nitride formed by the epitaxial growth by the MOCVD method, are formed in this order on the semiconductor substrate 11, in the same manner as in the semiconductor equipment 10 according to the embodiment shown in FIG. 1 and Examples 1 to 3.

In the element area 31, an n-channel MOS transistor having a drift region formed on the n-type layer 12 and a body region formed on the second p-type layer 14 is formed. In order to perform a normally-off operation in which a threshold value of the n-channel MOS transistor is +3 V or more, the impurity concentration of the first p-type layer 13 is designed according to a type and thickness of a gate insulating film and a crystal plane of gallium nitride, and is preferable set to 5×10¹⁷ cm⁻³ or more and 5×10¹⁸ cm⁻³ or less.

In the element area 31, a plurality of stripe-shaped trenches 71 arranged in parallel with each other, reaching from the surface of the second p-type layer 14 to the n-type layer 12, are formed. A width of each trench 71 is 2 μm. In the trench 71, a gate insulating film 72 of a SiO₂ film is formed on a side wall and a bottom surface, and a gate electrode 73 is formed inside the gate insulating film 72. For example, a TiN material can be used for the gate electrode 73. The gate electrodes 73 are connected to each other at end portions in a longitudinal direction (direction perpendicular to the paper surface in FIG. 14) such that the gate electrodes of the entire element are equipotential.

An n+ gallium nitride region 74 is formed on the second p-type layer 14 and the first p-type layer 13 on surfaces of gallium nitride layers on both sides of each of the trenches 71. The n+ gallium nitride region 74 is formed by implanting Si ions and performing an activation heat treatment. A source electrode 75 is in ohmic contact with the surface of the n+ gallium nitride region 74. The source electrode 75 is a film in which a Ti film and an Al film are laminated in this order.

An anode electrode 76 is in ohmic contact with the surface of the second p-type layer 14 between the trenches 71. The anode electrode 76 is in contact with the source electrode 75 to have the same potential. A Ni film is used for the anode electrode 76. The cathode electrode 18 formed on the back surface of the semiconductor substrate 11 also serves as a drain electrode.

In the semiconductor equipment 70 of Example 5, the isolation region 33 and the electric field relaxation region 32 are configured in the same manner as in Example 4. In the isolation region 33, in the impurity element implantation region 61, boron is distributed from the surface of the second p-type layer 14 to the bottom portion of the first p-type layer 13, and boron ions are implanted by multi-stage ion implantation with the maximum implantation energy set to 400 keV to sufficiently form the i-type layer. The impurity element implantation region 20 of the electric field relaxation region 32 is formed to the same depth as in Example 4. The total dose of the impurity element implantation region 20 is set to 1×10¹³ cm⁻². In the impurity element implantation region 61 of the isolation region 33, the total dose is set to 5×10¹⁴ cm⁻², but it is preferable to set the total dose to 3×10¹⁴ cm⁻² to 3×10¹⁵ cm⁻² from the viewpoint that the electric field concentration can be suppressed, in the same manner as in Example 4.

In the semiconductor equipment 70, when a positive bias is applied to the gate electrode 73, the trench MOS transistor is turned on, and an on-state current flows between the drain electrode (cathode electrode 18) and the source electrode 75. When a 0 (zero) V or negative bias is applied to the gate electrode 73, the trench MOS transistor is turned off, and when a reverse bias is applied between the drain electrode (cathode electrode 18) and the source electrode 75, a depletion layer spreads in the n-type layer 12, which exhibits withstand voltage characteristics.

In the trench MOS transistor to be formed in a gallium nitride epitaxial crystal layer in the element area 31, the impurity concentration of the p-type layer required for a normally-off design is usually set to approximately 1×10¹⁸ cm⁻³. On the other hand, in the electric field relaxation region 32, in an optimum design, the impurity concentration of the p-type layer is approximately 1×10¹⁷ cm⁻³, which is 1/10 of the impurity concentration in the element area. Therefore, it was difficult to reconcile the impurity concentrations in both regions in a single epitaxial growth of the p-type layer. In Example 5, by implanting boron into the first p-type layer 13 in the electric field relaxation region 32 to form the impurity element implantation region 20 having a lower impurity concentration than that of the first p-type layer 13 in the element area, the electric field concentration can be suppressed or avoided and an electric field design can be optimized.

In Example 5, the trench MOS transistor is formed in the element area 31, but the present invention is not limited to this configuration. For example, a planar MOS transistor or a high electron mobility transistor (HEMT) may be formed.

Although the preferred embodiments of the present invention have been described above in detail, the present invention is not limited to the relevant specific embodiments, and various modifications and changes can be made within the scope of the present invention described in the claims. In Examples 1 to 4, the gallium nitride crystal layer epitaxially grown on the gallium nitride substrate was used as the semiconductor epitaxial layer, but a group III nitride semiconductor epitaxial layer in which a part of gallium is substituted with aluminum (Al) or indium (In) may be used. In addition, a crystal layer of a group III nitride semiconductor epitaxially grown on a substrate such as a silicon carbide (SiC) substrate or a sapphire substrate instead of the gallium nitride substrate may be applied. As described above, in the present disclosure, it is particularly preferable to use a group III nitride semiconductor, but other wide bandgap semiconductors, for example, SiC, Ga₂O₃, and the like are also applicable. In addition, the embodiment and Examples 1 to 4 may be combined with each other. For example, each of the configurations of the impurity element implantation regions in the electric field relaxation regions of Examples 1 and 2 may be applied to the impurity element implantation regions in the electric field relaxation regions of Examples 3 and 4.

### INDUSTRIAL APPLICABILITY

The withstand voltage of the semiconductor equipment can be improved.

### REFERENCE SIGNS LIST

10, 40, 50, 60, 70: Semiconductor equipment
11: Semiconductor substrate
12: n-type layer
13: First p-type layer
14: Second p-type layer
16: Anode electrode
18: Cathode electrode
20, 51 to 53, 61: Impurity element implantation region
22: Mesa Groove
31: Element area
32: Electric field relaxation region
33: Isolation region
41: Inner implantation area
42: Outer implantation area

1-17. (canceled)

18. A semiconductor equipment comprising:
an element area having an n-type layer, a first p-type layer on the n-type layer, and a second p-type layer on the first p-type layer, the second p-type layer having an acceptor concentration higher than the first p-type layer; and
an electric field relaxation region surrounding the element area,
wherein in the electric field relaxation region, a region containing an impurity element that inactivates a part of acceptors in the first p-type layer and the second p-type layer is provided in the first p-type layer and the second p-type layer.

19. The semiconductor equipment according to claim 18, wherein in the electric field relaxation region, the region containing the impurity element is formed such that a plurality of sub-regions having different impurity element concentrations are successively formed from a side close to the element area to a side far from the element area, and the sub-region farther from the element area has a higher impurity element concentration than the sub-region closer to the element area.

20. The semiconductor equipment according to claim 19, further comprising:
an isolation region surrounding the electric field relaxation region,
wherein in the isolation region, a mesa structure that reaches the n-type layer is provided, and the region containing the impurity element is provided from a surface of the n-type layer to an inside of the n-type layer.

21. The semiconductor equipment according to claim 19, further comprising:
an isolation region surrounding the electric field relaxation region,
wherein in the isolation region, the first and second p-type layers extend, and the first and second p-type layers are formed such that the acceptors thereof are inactivated by the impurity element to form an insulation region.

22. The semiconductor equipment according to claim 18, wherein in the electric field relaxation region, the region containing the impurity element is formed by a plurality of sub-regions spaced apart from each other to surround the element area from a side close to the element area to a side far from the element area.

23. The semiconductor equipment according to claim 22, further comprising:
an isolation region surrounding the electric field relaxation region,
wherein in the isolation region, a mesa structure that reaches the n-type layer is provided, and the region containing the impurity element is provided from a surface of the n-type layer to an inside of the n-type layer.

24. The semiconductor equipment according to claim 22, further comprising:
an isolation region surrounding the electric field relaxation region,
wherein in the isolation region, the first and second p-type layers extend, and the first and second p-type layers are formed such that the acceptors thereof are inactivated by the impurity element to form an insulation region.

25. The semiconductor equipment according to claim 22, wherein widths of the plurality of sub-regions become wider from the side close to the element area toward the side far from the element area.

26. The semiconductor equipment according to claim 25, further comprising:
an isolation region surrounding the electric field relaxation region,
wherein in the isolation region, a mesa structure that reaches the n-type layer is provided, and the region containing the impurity element is provided from a surface of the n-type layer to an inside of the n-type layer.

27. The semiconductor equipment according to claim 25, further comprising:
an isolation region surrounding the electric field relaxation region,
wherein in the isolation region, the first and second p-type layers extend, and the first and second p-type layers are formed such that the acceptors thereof are inactivated by the impurity element to form an insulation region.

28. The semiconductor equipment according to claim 18, further comprising:
an isolation region surrounding the electric field relaxation region,
wherein in the isolation region, a mesa structure that reaches the n-type layer is provided, and the region containing the impurity element is provided from a surface of the n-type layer to an inside of the n-type layer.

29. The semiconductor equipment according to claim 18, further comprising:
an isolation region surrounding the electric field relaxation region,
wherein in the isolation region, the first and second p-type layers extend, and the first and second p-type layers are formed such that the acceptors thereof are inactivated by the impurity element to form an insulation region.

30. The semiconductor equipment according to claim 18, wherein the semiconductor equipment constitutes a vertical diode, and
in the element area, an anode electrode is formed on the second p-type layer, and a cathode electrode is formed on a back surface side of the n-type layer.

31. The semiconductor equipment according to claim 18, wherein the semiconductor equipment constitutes a vertical MOS power transistor, and
in the element area, a source electrode and a gate electrode are provided, a drift region is provided in the n-type layer, and a body region is provided in the first p-type layer.

32. The semiconductor equipment according to claim 18, wherein the impurity element includes at least one element of boron (B), nitrogen (N), oxygen (O), phosphorus (P), zinc (Zn), and iron (Fe).

33. The semiconductor equipment according to claim 18, wherein the impurity element is boron (B).

34. A manufacturing method for a semiconductor equipment, comprising:
a step of forming an n-type layer, a first p-type layer on the n-type layer, and a second p-type layer on the first p-type layer on a semiconductor substrate by epitaxial growth, the second p-type layer having an acceptor concentration higher than the first p-type layer;
a step of activating acceptors of the first and second p-type layers;
an implantation step of implanting impurity element ions for inactivating a part of the acceptors in the first p-type layer and the second p-type layer by a multi-stage ion implantation method into the first and second p-type layers in an electric field relaxation region surrounding an element area; and
a step of forming an electrode on a surface of the second p-type layer in the element area.

35. The manufacturing method for a semiconductor equipment according to claim 34, further comprising:
another implantation step of implanting impurity element ions into the first and second p-type layers by a multi-stage ion implantation method in a second sub-region on a side farther from the element area than a first sub-region close to the element area in the electric field relaxation region, after the implantation step.

36. The manufacturing method for a semiconductor equipment according to claim 35, wherein in the implantation step, the impurity element ions are implanted such that a plurality of sub-regions are formed to surround the element area from a side close to the element area to a side far from the element area.

37. The manufacturing method for a semiconductor equipment according to claim 34, further comprising:
a step of forming an isolation region by etching the first and second p-type layers in a region surrounding the electric field relaxation region to expose the n-type layer, after the implantation step.

38. The manufacturing method for a semiconductor equipment according to claim 34, further comprising:
another implantation step of implanting the impurity element ions into the first and second p-type layers by a multi-stage ion implantation method to inactivate the acceptors in an isolation region surrounding the electric field relaxation region, after the implantation step.

39. The manufacturing method for a semiconductor equipment according to claim 34, wherein the impurity element ions include at least one of boron (B) ions, nitrogen (N) ions, oxygen (O) ions, phosphorus (P) ions, zinc (Zn) ions, and iron (Fe) ions.

40. The manufacturing method for a semiconductor equipment according to claim 34, wherein the impurity element ions are boron (B) ions.
